(19) United States
(12) Patent Application Publication
(10) Pub. No.: US 2016/0027811 A1
(43) Pub. Date: Jan. 28, 2016

(54) THIN FILM TRANSISTOR, ARRAY SUBSTRATE AND DISPLAY DEVICE

(71) Applicant: BOE TECHNOLOGY GROUP CO., LTD., Beijing (CN)

(72) Inventors: Yanzhao LI, Beijing (CN); Gang WANG, Beijing (CN); Chunsheng JIANG, Beijing (CN); Jingfei FANG, Beijing (CN); Jingang FANG, Beijing (CN)

(73) Assignee: BOE TECHNOLOGY GROUP CO., LTD., Beijing (CN)

(21) Appl. No.: 14/430,138

(22) PCT Filed: May 12, 2014
(86) PCT No.: PCT/CN2014/077275

§ 371 Date: Mar. 20, 2015

(30) Foreign Application Priority Data
Dec. 31, 2013 (CN) 201310751059.X

(51) Int. Cl. H01L 27/12; H01L 29/04; H01L 29/24; H01L 29/786; H01L 29/06

(52) U.S. Cl. CPC H01L 27/1229; H01L 29/7869; H01L 29/0684; H01L 29/242; H01L 27/1225; H01L 29/04; H01L 29/78693; H01L 29/24

(57) ABSTRACT

Disclosed are a thin film transistor, an array substrate and a display device. The thin film transistor comprises a gate electrode, a gate insulating layer, an active layer, a source electrode and a drain electrode, wherein the active layer comprises at least two layers of semiconductor thin films, and the at least two layers of semiconductor thin films comprise at least one layer of monocrystalline semiconductor thin film.

### FIELD OF THE INVENTION

The present invention relates to the field of display technologies, and in particular, to a thin film transistor, an array substrate and a display device.

### DESCRIPTION OF THE PRIOR ART

Due to its high carrier mobility, good homogeneity and being preparable under room temperature, indium gallium zinc oxide (IGZO) has been widely researched to function as the channel material of a backplane thin film transistor (TFT) in place of monocrystalline and low temperature poly-silicon (LTPS), so that the industrialization of large-size panels such as active matrix organic light-emitting diode panel (AMOLED) and the like is realized.

However, at present, when IGZO semiconductor is used as the channel material of a TFT, the carrier mobility thereof is still low (about 10-20 cm²V⁻¹s⁻¹) in comparison with monocrystalline silicon and LTPS. The lower the carrier mobility of a TFT device is, the larger equivalent resistance thereof will be and the longer the charging and discharging time will be, which has become a severe bottleneck to the preparation of large-size panels.

### SUMMARY OF THE INVENTION

In view of this, the present invention provides a thin film transistor, thereby solving the problem of low carrier mobility of the existing oxide TFT devices.

Further, the invention provides an array substrate and a display device comprising the above thin film transistor.

In order to solve the above problem, the invention provides a thin film transistor, which comprises a gate electrode, a gate insulating layer, an active layer, a source electrode and a drain electrode; wherein, the active layer comprises at least two layers of semiconductor thin films, and the at least two layers of semiconductor thin films comprise at least one layer of monocrystalline semiconductor thin film.

Optionally, the at least two layers of semiconductor thin films are made of the same semiconductor material.

Optionally, the at least two layers of semiconductor thin films are made of different semiconductor materials.

Optionally, the semiconductor material is a metal oxide semiconductor, an elemental semiconductor or a non-oxide compound semiconductor.

Optionally, the at least two layers of semiconductor thin films are all monocrystalline semiconductor thin films, or comprise at least one layer of monocrystalline semiconductor thin film and at least one layer of amorphous semiconductor thin film.

Optionally, the at least two layers of semiconductor thin films comprise a amorphous indium gallium zinc oxide thin film, a monocrystalline indium gallium zinc oxide thin film and a amorphous indium gallium zinc oxide thin film that are set in turn.

Optionally, the at least two layers of semiconductor thin films comprise a monocrystalline indium gallium zinc oxide thin film, a monocrystalline cuprous oxide thin film and a monocrystalline indium gallium zinc oxide thin film that are set in turn.

Optionally, the at least two layers of semiconductor thin films comprise a amorphous indium gallium zinc oxide thin film and a monocrystalline cuprous oxide thin film that are set in turn.

The invention further provides an array substrate, which comprises the above thin film transistor.

The invention further provides a display device, which comprises the above array substrate.

The above technical solutions of the invention have the following beneficial technical effects:

Since the active layer of the thin film transistor has a structure that comprises at least two layers of semiconductor thin films, wherein, one part of the semiconductor thin film may function as a carrier-generating region, and the other part of the semiconductor thin film may function as a carrier-transmitting region, the carrier-generating region and the carrier-transmitting region are separated, thereby it may be avoided that the transmission speed of the carriers is lowered during transmission because the carriers are scattered by too many ionized impurities, thus the carrier mobility of the TFT device may be improved.

### BRIEF DESCRIPTION OF THE DRAWINGS

FIG. 1 shows a structural representation of a thin film transistor according to Embodiment 1 of the invention;

FIG. 2 shows a structural representation of a thin film transistor according to Embodiment 2 of the invention;

FIG. 3 shows a schematic flow chart of a method for preparing the thin film transistor according to Embodiment 1 of the invention;

FIG. 4 shows a schematic energy band diagram of one active layer of a thin film transistor according to one embodiment of the invention;

FIG. 5 shows a schematic energy hand diagram of another active layer of the thin film transistor according to one embodiment of the invention;

FIG. 6 shows a structural representation of a thin film transistor according to Embodiment 3 of the invention; and

FIG. 7 shows a structural representation of a thin film transistor according to Embodiment 4 of the invention.

### DETAILED DESCRIPTION OF THE PREFERRED EMBODIMENTS

During the research process on the carrier mobility of an oxide TFT, the inventors of the invention find that, the channel (i.e., active layer) of an existing TFT device that employs IGZO semiconductor as the channel material has a single-layer structure, that is, it is integrally made of a layer of amorphous oxide, and such a single-layer structure causes the superposition of a carrier-generating region and a carrier-transmitting region, as a result, during transmission, the transmission speed of carriers is lowered because the carriers are scattered by too many ionized impurities, which is reflected by the lowering of the carrier mobility of the TFT device.

As directed to such a problem, an embodiment of the invention provides a thin film transistor, and an array substrate and a display device that comprises the thin film transistor. In order to make the technical problem to be solved, the technical solutions and the advantages of the invention more apparent, a detailed description will be given below in conjunction with the drawings and the specific embodiments.

In order to solve the problem of low carrier mobility of TFT device with a structure of single-layer active layer, one embodiment of the invention provides a thin film transistor, which includes a gate electrode, a gate insulating layer, an active layer, a source electrode and a drain electrode that are manufactured on abuse substrate, wherein, the active layer includes at least two layers of semiconductor thin films, and the at least layers of semiconductor thin films include at least one layer of monocrystalline semiconductor thin film.

In the embodiment of the invention, the base substrate may be made of a transparent material such as glass or quartz, etc., or it may be made of a nontransparent material such as ceramics and metal, etc.

In the embodiment of the invention, the gate electrode, the source electrode and the drain electrode may be made of a metal, for example, molybdenum (Mo), aurum (Au), aluminum (Al), chromium (Cr) and titanium (Ti), etc., or an alloy thereof; or, they may be made of other composite conducting materials.

In the embodiment of the invention, the gate insulating layer maybe made of an insulating material such as silicon oxide (SiO₂) and silicon nitride (SiNₓ), etc.

At least two layers of semiconductor thin films of the active layer may be made of the same semiconductor material, or may be made of different semiconductor materials. The semiconductor material may be a metal oxide semiconductor, an elemental semiconductor (for example, Si) or a non-oxide compound semiconductor (for example, II-VI group semiconductor). In other words, the at least two layers of semiconductor thin films may be all made of the same metal oxide semiconductor, or they may be all made of the same elemental semiconductor, or they may be all made of the same non-oxide compound semiconductor; or, the at least two layers of semiconductor thin films may be made of different semiconductor materials, for example, one layer may be made of a metal oxide semiconductor, and the other layer may be made of an elemental semiconductor.

Additionally, the at least two layers of semiconductor thin films may be all monocrystalline semiconductor thin films, or may comprise at least one layer of monocrystalline semiconductor thin film and at least one layer of amorphous semiconductor thin film. That is, the at least two layers of semiconductor thin films includes at least one layer of monocrystalline semiconductor thin film.

Optionally, the at least two layers of semiconductor thin films may include a amorphous indium gallium zinc oxide thin film, a monocrystalline iridium gallium zinc oxide thin film and a amorphous indium gallium zinc oxide thin film that are set in turn.

Optionally, the at least two layers of semiconductor thin films may include a monocrystalline indium gallium zinc oxide thin film, a monocrystalline cuprous oxide thin film and a monocrystalline indium gallium zinc oxide thin film that are set in turn.

Optionally, the at least two lavers of semiconductor thin films may include a amorphous indium gallium zinc oxide thin film and a monocrystalline cuprous oxide thin film that are set in turn.

The active layer of the thin film transistor provided by the above embodiment has a structure that includes at least two layers of semiconductor thin films, wherein, a part of the semiconductor thin film may function as a carrier-generating region, and the other part of the semiconductor thin film may function as a carrier-transmitting region, thus the carrier-generating region and the carrier-transmitting region are separated from each other, so that it may be avoided that the transmission speed of the carriers is lowered during transmission because the carriers are scattered by too many ionized impurities, thereby the carrier nobility of the TFT device may be improved.

The structure of the thin film transistor according to the embodiments of the invention will be illustrated in detail below via specific embodiments.

### Embodiment 1

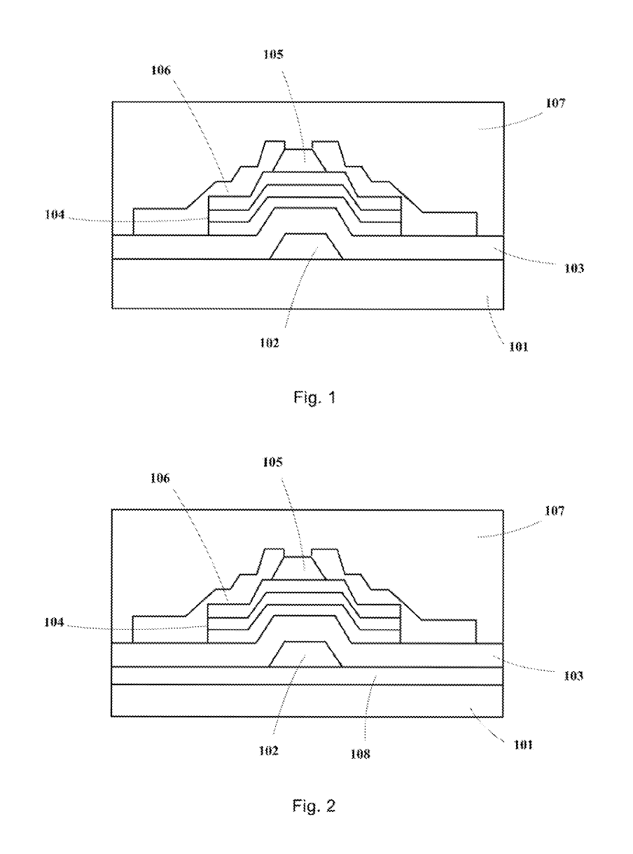

Referring to FIG. 1, it shows a structural representation of a thin film transistor according to Embodiment 1 of the invention, wherein, the thin film transistor includes a gate electrode 102, a gate insulating layer 103, an active layer 104, an etch stop layer 105, a source/drain electrode 106 and a passivation layer 107 that are manufactured on a base substrate 101. The active layer 104 includes three layers of semiconductor thin films, and at least one layer of semiconductor thin film is a amorphous semiconductor thin film.

The etch stop layer 105 is configured for preventing the active layer 104 from being damaged by the wet etching performed on the source/rain electrode 106.

The passivation layer 107 is configured for protecting the other layers of the thin film transistor, and the passivation layer 107 may be made of an insulating material such as silicon oxide, silicon nitride or an organic material, etc.

### Embodiment 2

Referring to FIG. 2, it shows a structural representation of a thin film transistor according to Embodiment 2 of the invention. In comparison with the thin film transistor of Embodiment 1, in the thin film transistor of the Embodiment 2, a buffer layer 108 is added between the base substrate 101 and the gate electrode 102, the buffer layer 108 may be made of an insulating material such as silicon dioxide, etc.

The three layers of semiconductor thin films of the active layer 104 in the above Embodiments 1 and 2 may all be monocrystalline semiconductor thin films; or, a part thereof may be a monocrystalline semiconductor thin film, and a part thereof may be a amorphous semiconductor thin film. A thin transistor with such a structure is also referred to as a thin film transistor with a superlattice structure.

A method for preparing the thin film transistor of Embodiment 1 will be illustrated below respectively in an example in which the three layers of semiconductor thin films of the active layer 104 are all monocrystalline semiconductor thin films and in an example in which a part thereof is a monocrystalline semiconductor thin film and a part thereof is a amorphous semiconductor thin film.

1) A method for preparing a thin film transistor where the active layer includes three layers of monocrystalline semiconductor thin films

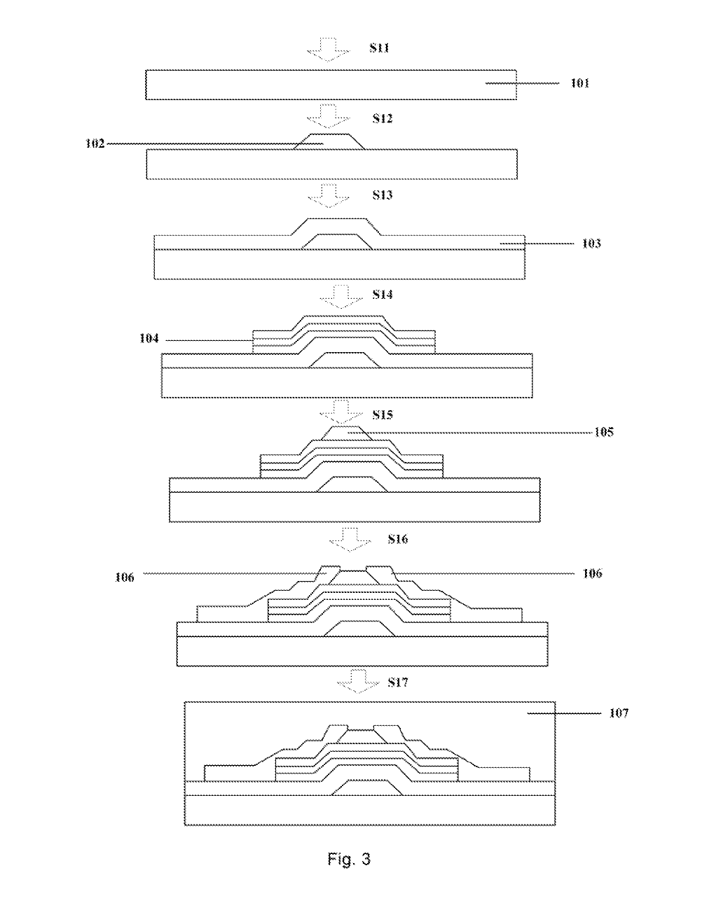

As shown in FIG. 3, the preparation method includes Steps S11-S17 below.

Step S11: providing a base substrate 101, and cleaning it in a standard method.

Optionally, a buffer layer 108 may be deposited on the base substrate 101. Specifically, chemical vapor deposition (CVD) may be employed to deposit a SiO₂ thin film with a thickness 200 nm, which functions as the buffer layer 108, on the base substrate 101. In this embodiment, no buffer layer 108 is deposited.

Step S12: depositing a gate metal Mo layer with a thickness of 200 nm on the base substrate 101 via sputtering, and photoetching or etching the gate metal Mo layer to obtain the pattern of a required gate electrode 102.

Step S13: depositing a SiO₂ layer with a thickness of 150 nm, which functions as a gate insulating layer 103, on the gate electrode 102 under 370° C. via CVD.

Step S14: depositing an IGZO thin film with a thickness of about 10 nm on the gate insulating layer 103 via metal organic chemical vapor deposition (MOCVD), wherein the volume content of oxygen in the gas atmosphere may be 10%-80% during deposition;

depositing a cuprous oxide (Cu₂O) thin film with a thickness of about 20 nm on the IGZO thin film via molecular beam epitaxial growth (MBE), wherein the volume content of oxygen in the gas atmosphere may be 10%-80% during deposition, and preferably, less than or equal to 15%; and

depositing an IGZO thin film with a thickness of about 10 nm on the Cu₂O thin film via metal organic chemical vapor deposition (MOCVD), wherein the volume content of oxygen in the gas atmosphere may be 10%-80% during deposition; and

photoetching or etching the IGZO thin film to obtain the pattern of a required active layer 104 (i.e., a channel region of the TFT).

Step S15: depositing a SiO₂ layer with a thickness of about 50 nm on the active layer 104, and photoetching or etching the SiO₂ layer to obtain an etch stop layer 105.

Step S16: depositing a source and drain metal Mo/Al layer with a thickness of about 200 nm via sputtering, and photoetching or etching the source and drain metal Mo/Al layer to obtain the pattern of a required source/drain electrode 106.

Step S17: depositing a SiO₂ layer with a thickness of about 100-500 nm via CVD, and forming a passivation layer 107. Additionally, it further needs to photoetch or etch the passivation layer 107 to obtain a connection hole, which is configured for the subsequent display panel process.

By the above steps, the preparation of a thin film transistor where the active layer includes three layers of monocrystalline semiconductor thin films is completed.

The three layers of semiconductor thin films included in the active layer 104 of the above thin film transistor are all monocrystalline semiconductor thin films (IGZO/Cu₂O/IGZO). Referring to FIG. 4, in such a structure, a quantum well is formed between the energy band of the upper and lower monocrystalline semiconductor thin films and the energy band of the intermediate monocrystalline semiconductor thin film, and because Cu₂O is a p-type semiconductor, the upper and lower IGZO layers provide hole carriers thereto, and the hole carriers may be constrained in the quantum well by precisely controlling the width of the quantum the thickness of the Cu₂O layer); in addition, because the Cu₂O layer is monocrystalline, the hole carrier will not be scattered by too many ionized impurities, so that the mobility can be improved, thus a p-type TFT device with a high mobility can be obtained.

After the preparation of the TFT device is completed, an ITO electrode may be deposited thereon via sputtering, and then photoetched or etched to obtain the pattern of a pixel region or a subpixel region of the array substrate, and finally, an array substrate of a display panel is formed. If an OLED display apparatus is to be manufactured, it continues to deposit an acrylic material via spin coating, then photoetch or etch the acrylic material and cure it to form a pixel defining layer with a thickness of about 1.5 μm, and finally the backplane of an OLED display apparatus is formed.

2) A method for preparing a thin film transistor where the active layer includes amorphous monocrystalline/amorphous semiconductor thin films.

The preparation method includes Steps S21-S27 below.

Step S21: providing a base substrate 101, and cleaning it in a standard method.

Optionally, a buffer layer 108 may be deposited on the base substrate 101. Specifically, chemical vapor deposition (CVD) may be employed to deposit a SiO₂ thin film with a thickness 200 nm, which functions as the buffer layer 108, on the base substrate 101. In this embodiment, no buffer layer 108 is deposited.

Step S22: depositing a gate metal Mo layer with a thickness of 200 nm on the base substrate 101 via sputtering, and photoetching or etching the gate metal Mo layer to obtain the pattern of a required gate electrode 102.

Step S23: depositing a SiO₂ layer with a thickness of 150 nm, which functions as a gate insulating layer 103, on the gate electrode 102 under 370° C. via CVD.

Step S24: depositing an IGZO amorphous thin film with thickness of about 10 nm on the gate insulating layer 103 via sputtering, wherein the volume content of oxygen the gas atmosphere may be 10%-80% during deposition;

depositing an IGZO monocrystalline thin film with a thickness of about 20 nm on the IGZO amorphous thin film via MOCVD, wherein the volume content of oxygen in the gas atmosphere may be 10%-80% during deposition;

depositing an IGZO amorphous thin film with a thickness of about 10 nm on the IGZO monocrystalline thin film via sputtering, wherein the volume content of oxygen in the gas atmosphere may be 10%-80% during deposition; and

photoetching or etching the IGZO thin film to obtain the pattern of a required active layer 104 (i.e., a trench region of the TFT).

Step S25: depositing a SiO₂ layer with a thickness of about 50 nm on the active layer 104, and photoetching or etching the SiO₂ layer to obtain an etch stop layer 105.

Step S26: depositing a source and drain metal Mo/Al layer with a thickness of about 200 nm via sputtering, and photoetching or etching the source and drain metal Mo/Al layer to obtain the pattern of a required source/rain electrode 106.

Step S27: depositing a SiO₂ layer with a thickness of about 100-500 nm via CVD, and forming a passivation layer 107. Additionally, it further needs to photoetch or etch the passivation layer 107 to obtain a connection hole, which is configured for the subsequent display panel process.

By the above steps, the preparation of a thin film transistor where the active layer includes amorphous/monocrystalline/amorphous semiconductor thin films is completed.

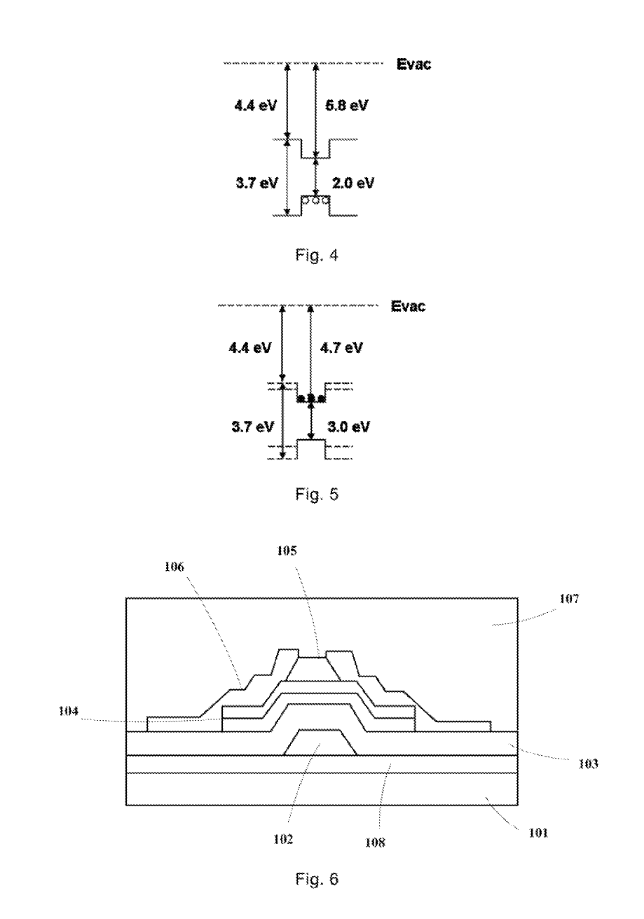

The intermediate semiconductor thin film of the three layers of semiconductor thin films included in the active layer 104 of the above thin film transistor is monocrystalline, and the upper and lower semiconductor thin film layers are amorphous (a-IGZO/c-IGZO/a-IGZO). Referring to FIG. 5, in such a structure, a quantum well is formed between the energy hand of the upper and lower amorphous semiconductor thin films and the energy band of the intermediate monocrystalline semiconductor thin film, and because c-IGZO is an n-type semiconductor, the upper and lower a-IGZO layers provide carriers thereto, and the carriers may be constrained in the quantum well by precisely controlling the width of the quantum well (i.e., the thickness of the c-IGZO layer); in addition, because the c-IGZO layer is monocrystalline, the carriers are blocked lightly during transmission, so that the mobility can be improved, thus an n-type TFT device with a high mobility can be obtained. Theoretically, the carrier mobility of a TFT device with such a structure may be improved from 10 cm⁻²V⁻¹s⁻¹ to 50 cm²V⁻¹s⁻¹.

After the preparation of the TFT device is completed, an no electrode may be deposited thereon via sputtering and then photoetched or etched to obtain the pattern of a pixel region or a subpixel region, and finally, an array substrate of a display panel is formed. If an OLED display apparatus is to be manufactured, it continues to deposit an acrylic material via spin coating, then photoetch the acrylic material and cure it to form a pixel defining layer with a thickness of about 1.5 μm, and finally the backplane of an OLED display device may be formed.

### Embodiment 3

Referring to FIG. 6, it shows a structural representation of a thin film transistor according to Embodiment 3 of the invention. The difference between the thin film transistor of Embodiment 3 and the thin film transistor of Embodiment 1 lies in that, the active layer 104 of Embodiment 3 includes two layers of semiconductor thin films.

The two layers of semiconductor thin films of the active layer 104 of Embodiment 3 may be all monocrystalline semiconductor thin films; or a layer thereof maybe a monocrystalline semiconductor thin film, and another layer thereof may be an amorphous semiconductor thin film.

A method for preparing the thin film transistor of Embodiment 3 will be illustrated below in an example in which the two layers of semiconductor thin films of the active layer 104 are amorphous/monocrystalline semiconductor thin films.

3) A method for preparing a thin film transistor where the active layer includes a amorphous/monocrystalline semiconductor thin film

The preparation method includes Steps S31-S37 below.

Step S31: providing a base substrate 101, and cleaning it in a standard method.

Optionally, a buffer layer 108 may be deposited on the base substrate 101. Specifically, chemical vapor deposition (CVD) may be employed to deposit a SiO₂ thin film with a thickness 200 nm, which functions as the buffer layer 108, on the base substrate 101. In this embodiment, no buffer layer 108 is deposited.

Step S32: depositing a gate metal Mo layer with a thickness of 200 nm on the base substrate 101 via sputtering, and photoetching or etching the gate metal Mo layer to obtain the pattern of a desirable gate electrode 102.

Step S33: depositing a SiO₂ layer with a thickness of 150 mm, which functions as a gate insulating layer 103, on the gate electrode 102 under 370° C. via CVD.

Step S34: depositing IGZO amorphous thin film with a thickness of about 10 nm on the gate insulating layer 103 via sputtering, wherein the volume content of oxygen in the gas atmosphere may be 10%-80% during deposition;

depositing a Cu₂O monocrystalline thin film with a thickness of about 20 nm on the IGZO amorphous thin film, wherein the volume content of oxygen in the gas atmosphere may be 10%-80% during deposition, and preferably, less than or equal to 15%;

photoetching or etching the IGZO thin film to obtain the pattern of a required active layer 104 (i.e., a channel region of the TFT).

Step S35: depositing a SiO₂ layer with a thickness of about 50 nm on the active layer 104, and photoetching or etching the SiO₂ layer to obtain an etch stop layer 105.

Step S36: depositing a source and drain metal Mo/Al layer with a thickness of about 200 nm via sputtering, and photoetching or etching the source and drain metal Mo/Al layer to obtain the pattern of a desirable source/rain electrode 106.

Step S37: depositing a SiO₂ layer with a thickness of about 100-500 nm via CVD, and forming a passivation layer 107. Additionally, it further needs to photoetch or etch the passivation layer 107 to obtain a connection hole, which is configured for the subsequent display panel process.

By the above steps, the preparation of a thin film transistor where the active layer includes a amorphous/monocrystalline semiconductor thin film is completed.

In the two-layer structure included in the active layer 104 of the above thin film transistor, one layer is amorphous, and the other layer is monocrystalline (a-IGZO/c-Cu₂O). Theoretically, the TFT device may realize duplex-type channel conducting.

After the preparation of the TFT device is completed, an ITO electrode may be deposited thereon via sputtering and then photoetched or etched to obtain the pattern of a pixel region or a subpixel region, and finally a display panel may be formed.

### Embodiment 4

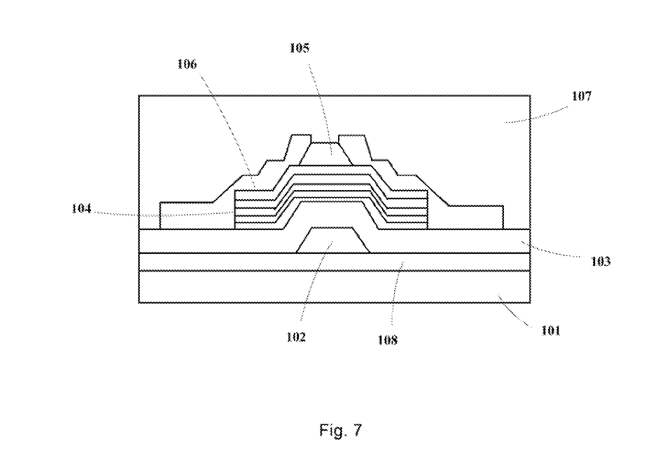

Referring to FIG. 7, it shows a structural representation of a thin film transistor according to Embodiment 4 of the invention. The difference between the thin film transistor of Embodiment 4 and the thin film transistor of Embodiment 1 lies in that, the active layer 104 of Embodiment 4 includes five layers of semiconductor thin films.

The five layers of semiconductor thin films of the active layer 104 in Embodiment 4 may all be monocrystalline semiconductor thin films; or, a part thereof may be a monocrystalline semiconductor thin film, and a part thereof may be a amorphous semiconductor thin film. Such a thin film transistor with a structure of periodic thickness is also referred to as a thin film transistor with a superlattice structure.

A method for preparing a thin film transistor of Embodiment 4 will be illustrated below in an example in which the five layers of semiconductor thin films of the active layer 104 are all monocrystalline semiconductor thin films.

4) A method for preparing a thin film transistor where the active layer includes five layers of monocrystalline semiconductor thin films

The preparation method includes the steps below.

Step S41: providing a base substrate 101, and cleaning it in a standard method.

Optionally, a buffer layer 108 may be deposited on the base substrate 101. Specifically, a chemical vapor deposition (CVD) may be employed to deposit a SiO₂ thin film with a thickness 200 nm, which functions as the buffer layer 108, on the base substrate 101. In this embodiment, no buffer layer 108 is deposited.

Step S42: depositing a gate metal Mo layer with a thickness of 200 nm on the base substrate 101 via sputtering, and photoetching or etching the gate metal Mo layer to obtain the pattern of a desirable gate electrode 102.

Step S43: depositing a SiO₂ layer with a thickness of 150 nm, which functions as a gate insulating layer 103 on the gate electrode 102 under 370° C. via CVD.

Step S44: depositing an IGZO thin film with a thickness of about 10 nm on the gate insulating layer 103 via metal organic chemical vapor deposition (MOCVD), wherein the volume content of oxygen in the gas atmosphere may be 10%-80% during deposition;

depositing a cuprous oxide (Cu₂O) thin film with a thickness of about 10 nm on the IGZO thin film via a molecular beam epitaxial growth (MBE), wherein the volume content of oxygen in the gas atmosphere may be 10%-80% during deposition, and preferably, less than or equal to 15%;

forming a structure of five layers of semiconductor thin films as below via such overlapped deposition: IGZO 10 nm/Cu₂O 10 nm/IGZO 10 nm/Cu₂O 10 nm/IGZO 10 nm;

photoetching or etching the IGZO thin film to obtain the pattern of a required active layer 104 (i.e., a channel region of the TFT).

Step S45: depositing a SiO₂ layer with a thickness of about 50 nm on the active layer 104, and photoetching or etching the SiO₂ layer to obtain an etch stop layer 105.

Step S46: depositing a source and drain metal Mo/Al layer with a thickness of about 200 nm via sputtering, and photoetching the source and drain metal Mo/Al layer to obtain the pattern of a desirable source/rain electrode 106.

Step S47: depositing a SiO₂ layer with a thickness of about 100-500 nm via CVD, and forming a passivation layer 107. It further needs to photoetch or etch the passivation layer 107 to obtain a connection hole, which is configured for the subsequent display panel process.

By the above steps, the preparation of a thin film transistor where the active layer includes five layers of monocrystalline semiconductor thin films is completed.

After the preparation of the TFT device is completed, an no electrode may be deposited thereon via sputtering, then photoetched or etched to obtain the pattern of a pixel region or a subpixel region. At last, an acrylic material is deposited via spin coating, and photoetched and cured to obtain a pixel defining layer with a thickness of about 1.5 μm, and a display panel is finally formed.

It may be seen from the above embodiments that, the number of layers of the semiconductor thin films of the active layer in the thin film transistor according to the embodiments of the invention may be as follows:

1) a double-layer structure;

2) a three-layer structure;

3) a more-than-three layer structure.

Each layer of semiconductor thin film of the active layer may have a homogeneous structure of a heterogeneous structure. The thickness of each semiconductor thin film needs to be determined via quantum calculation so as to realize the constraint of carriers. Under normal conditions, the thickness of an intermediate semiconductor thin film needs to be precisely controlled.

Further, the material of each layer of semiconductor thin film of the active layer may be as follows:

1) the layers of the multi-layer structure are all made of one and the same metal oxide semiconductor;

2) the layers of the multi-layer structure are all made of one and the same elemental semiconductor, for example, Si and the like;

3) the layers of the multi-layer structure are all made of one and the same non-oxide compound semiconductor, for example, a II-VI group semiconductor, etc.;

4) the layers of the multi-layer structure are made of different semiconductors.

In addition, each layer of semiconductor thin film of the active layer may be monocrystalline amorphous:

1) the layers of the multi-layer structure are all monocrystalline semiconductor thin films;

2) the layers of the multi-layer structure are all amorphous semiconductor thin films; and

3) the layers of the multi-layer structure include monocrystalline semiconductor thin films and amorphous semiconductor thin films at the same time.

The above embodiments are all illustrated by taking a TFT with a bottom gate structure (i.e., the gate electrode is located under the active layer) as an example. It may be understood that, in other embodiments of the invention, the TFT may also have other structures, which specifically includes:

1) a bottom gate structure;

2) a top gate structure (the gate electrode is located above the active layer);

3) an overlapped or anti-overlapped structure (the gate electrode and the source-drain electrode are located on the two sides of the active layer respectively); and

a coplane or anti-coplane structure (the gate electrode and the source-drain electrode are located on the same side of the active layer).

The TFT according to the embodiments of the invention may be an n-type conducting TFT, a p-type conducting TFT, or a duplex type conducting TFT.

Additionally, in the method for preparing the above thin film transistor, the deposition process of the active layer is not limited, and specifically, the following modes may be employed:

1) a monocrystalline semiconductor thin film is deposited via MOCVD or MBE;

2) an intermediate active layer is deposited via PECVD or Sputtering process; and

3) other processes, for example, solution sedimentation and the like.

One embodiment of the invention further provides an array substrate, which includes the above thin film transistor.

One embodiment of the invention further provides a display device, which includes the above array substrate. Specifically, the display device may be a display panel, a liquid crystal TV set, a mobile phone and a liquid crystal display, etc.

The above description only shows some representative embodiments of invention. It should be pointed out that, for a person skilled in the art, various improvements and modifications may also be made without departing from the principles of the invention, and all these improvements and modifications should be construed as pertaining to the protection scope of the invention.

1. A thin film transistor, comprising: a gate electrode, a gate insulating layer, an active layer, a source electrode and a drain electrode, wherein the active layer comprises at least two layers of semiconductor thin films, and the at least two layers of semiconductor thin films comprise at least one layer of monocrystalline semiconductor thin film.

2. The thin film transistor according to claim 1, wherein the at least two layers of semiconductor thin films are made of the same semiconductor material.

3. The thin film transistor according to claim 1, wherein the at least two layers of semiconductor thin films are made of different semiconductor materials.

4. The thin film transistor according to claim 2, wherein the semiconductor material is a metal oxide semiconductor, an elemental semiconductor or a non-oxide compound semiconductor.

5. The thin film transistor according to claim 1, wherein the at least two layers of semiconductor thin films are all monocrystalline semiconductor thin films, or comprise at least one layer of monocrystalline semiconductor thin film and at least one layer of amorphous semiconductor thin film.

6. The thin film transistor according to claim 5, wherein the at least two layers of semiconductor thin films comprise an amorphous indium gallium zinc oxide thin film, a monocrystalline indium gallium zinc oxide thin film and an amorphous indium gallium zinc oxide thin film that are set in turn.

7. The thin film transistor according to claim 5, wherein the at least two layers of semiconductor thin films comprise a monocrystalline indium gallium zinc oxide thin film, a monocrystalline cuprous oxide thin film and a monocrystalline indium gallium zinc oxide thin film that are set in turn.

8. The thin film transistor according to claim 5, wherein the at least two layers of semiconductor thin films comprise an amorphous indium gallium zinc oxide thin film and a monocrystalline cuprous oxide thin film that are set in turn.

9. An array substrate, comprising the thin film transistor according to claim 1.

10. A display device, comprising the array substrate according to claim 9.

11. The thin film transistor according to claim 3, wherein the semiconductor material is a metal oxide semiconductor, an elemental semiconductor or a non-oxide compound semiconductor.

12. The array substrate according to claim 9, wherein the at least two layers of semiconductor thin films are made of the same semiconductor material.

13. The array substrate according to claim 9, wherein the at least two layers of semiconductor thin films are made of different semiconductor materials.

14. The array substrate according to claim 12, wherein the semiconductor material is a metal oxide semiconductor, an elemental semiconductor or a non-oxide compound semiconductor.

15. The array substrate according to claim 13, wherein the semiconductor material is a metal oxide semiconductor, an elemental semiconductor or a non-oxide compound semiconductor.

16. The array substrate according to claim 9, wherein the at least two layers of semiconductor thin films are all monocrystalline semiconductor thin films, or comprise at least one layer of monocrystalline semiconductor thin film and at least one layer of amorphous semiconductor thin film.

17. The array substrate according to claim 16, wherein the at least two layers of semiconductor thin films comprise an amorphous indium gallium zinc oxide thin film, a monocrystalline indium gallium zinc oxide thin film and an amorphous indium gallium zinc oxide thin film that are set in turn.

18. The array substrate according to claim 16, wherein the at least two layers of semiconductor thin films comprise a monocrystalline indium gallium zinc oxide thin film, a monocrystalline cuprous oxide thin film and a monocrystalline indium gallium zinc oxide thin film that are set in turn.

19. The array substrate according to claim 16, wherein the at least two layers of semiconductor thin films comprise an amorphous indium gallium zinc oxide thin film and a monocrystalline cuprous oxide thin film that are set in turn.

20. The display device according to claim 19, wherein the at least two layers of semiconductor thin films are made of the same semiconductor material.
